(19) United States
(12) Patent Application Publication
(10) Pub. No.: US 2024/0321578 A1
(43) Pub. Date: Sep. 26, 2024

(54) METHOD FOR PREPARING WAFER-SCALE TWO-DIMENSIONAL MATERIAL ARRAYS

(71) Applicant: Fudan University, Shanghai (CN)

(72) Inventors: Liwei LIU, Shanghai (CN); Zhenggang CAI, Shanghai (CN); Siwei XUE, Shanghai (CN); Peng ZHOU, Shanghai (CN)

(21) Appl. No.: 18/680,924

(22) Filed: May 31, 2024

(30) Foreign Application Priority Data
Sep. 12, 2023 (CN) 202311169355.9

(51) Int. Cl. H01L 21/02; H01L 29/786

(52) U.S. Cl. CPC H01L 21/02568; H01L 21/02499; H01L 21/0262; H01L 29/78681

(57) ABSTRACT

A method for preparing a wafer-scale two-dimensional (2D) material array includes the following steps. Water and alcohol solvent are mixed to obtain a mixed solution. A polydimethylsiloxane (PDMS) stamp with micro posts is prepared. A monolayer two-dimensional transition metal dichalcogenides (2D-TMDs) film is continuously grown on a growth substrate. The PDMS stamp is put upside down to allow the micro posts to adhere to the monolayer 2D-TMDs film, so as to obtain a PDMS stamp-2D-TMDs film-growth substrate combination. The PDMS stamp-2D-TMDs film-growth substrate combination is immersed in the mixed solution to separate the monolayer 2D-TMDs film from the growth substrate. A portion of the monolayer 2D-TMDs film which is not in contact with upper surfaces of the micro posts is removed to obtain a patterned 2D-TMDs film. The patterned 2D-TMDs film is transferred to a target substrate to obtain the wafer-scale 2D material array.

### CROSS-REFERENCE TO RELATED APPLICATIONS

This application claims the benefit of priority from Chinese Patent Application No. 202311169355.9, filed on Sep. 12, 2023. The content of the aforementioned application, including any intervening amendments thereto, is incorporated herein by reference in its entirety.

### TECHNICAL FIELD

This application relates to transfer of two-dimensional atomic crystal materials, and more particularly to a method for preparing wafer-scale two-dimensional (2D) material arrays.

### BACKGROUND

Two-dimensional transition metal dichalcogenides (TMDs) represented by MoS₂ and WSe₂ et al have attracted extensive attention in the design and construction of new two-dimensional electronic devices due to their excellent structural and electrical properties, such as dangling-bond-free surface, atomically thin body thickness, comparable field-effect mobility, and an inherent propensity to adhere together through van der Waals (vdW) force. These characteristics present compelling prospects for pioneering advancement in device applications. In particular, the absence of dangling bonds on the surface can significantly reduce the carrier scatting. Thus, the gate electrode still exhibits an effective control of the 2D channel when the gate length of MoS₂ transistor is scaled down to sub-1 nm, positioning 2D integrated circuits as a viable alternative beyond silicon.

It has been reported that, the continual optimization of the materials growth technology and the device fabrication processes have led to impressive performance metrics in 2D devices (especially MoS₂-based transistors), including an ultralow contact resistance of 123 Ω·μm, a high carrier mobility (μ) of >100 cm²·V⁻¹·s⁻¹, a large saturation current (Iₒₙ) of 1.27 mA/μm at V_{DS}=2.5 V, and a high on/off ratio of >10⁸. The carrier mobility of 2D MoS₂-FETs is comparable to amorphous silicon based thin film transistors (α-Si TFTs), while the leakage current (10⁻¹³ μA/μm) is as low as oxide semiconductor based thin film transistors (e.g., indium-gallium-zinc-oxide thin-film transistors (IGZO-TFTs)) which demonstrates its potential application in the construction of 2D pixel circuits (e.g., image sensors, photovoltaic imaging, and micro-LED display).

Currently, extensive researches have been focused on 2D devices in micro-scale range. For example, 2D transistors have shown promising applications as high-sensitivity active pixel image sensor. The image sensor typically contains a phototransistor and a switch transistor, each serving distinct functions in image capture and image processing. The proposed in-sensing processing, each pixel based on a single programmable MoS₂ phototransistor, could streamline the crossbar architecture, resulting in reduction in footprint and energy consumption. Other applications, like skin-attachable tactile sensor, machine vision processor have also been demonstrated using micro-scale MoS₂ pixel arrays. Moreover, leveraging their high on saturation current and low leakage current properties, the micro-scale MoS₂-FETs exhibit advantages as high-performance active-matrix pixel circuits for micro-LED or OLED displays. These endeavors collectively represent successful attempts to promote micro-scale 2D devices into potential applications. In terms of the display performance, for a micro-LED display with a resolution of 320×240 pixels, 76,800 grains need to be integrated; and for a micro-LED display with a resolution of 1280×720 pixels, more than 770,000 grains need to be integrated. Therefore, to achieve the integration of large-scale grains onto a wafer, it is first required to transfer two-dimensional material arrays to the wafer scale, followed by deposition of source electrode and drain electrode on each array to obtain 2D FETs arrays, and interconnect the 2D arrays to obtain the two-dimensional driver circuit.

Currently, the 2D materials are obtained mainly by the mechanical exfoliation method and chemical vapor deposition (CVD) method. With the advancement of research and the development of growth technique, the continuous preparation of wafer-scale two-dimensional thin-film materials (e.g., MoS₂, h-BN, and WSe₂) has been preliminarily achieved by the CVD method. Compared to the traditional mechanical exfoliation method, the CVD method can solve the problems of small lateral dimensional size and difficult control in the number of layers to a certain extent. However, in the construction process of a new two-dimensional electronic devices, it is generally required to transfer grown 2D materials to a new target substrate (e.g., SiO₂/Si substrate or flexible polyethylene terephthalate (PET) substrate) to achieve the compatibility with the silicon-based semiconductor preparation process or the preparation of flexible electronic devices.

The use of a 2D material transfer platform to localize and transfer different 2D materials is a common method for the development and characterization of prototype devices in laboratory. The commonly used transfer methods include dry transfer methods and wet transfer methods, in which a flexible organic polymer, such as polymethyl methacrylate (PMMA), polydimethylsiloxane (PDMS), polystyrene (PS), and polyvinyl acetate (PVA), is often employed as a transfer medium. The transfer of micrometer (μm)-scale and centimeter (cm)-scale 2D materials has been achieved through such methods. However, in order to realize a high-density two-dimensional electronic devices integration, it often requires photoresist spin-coating, optical exposure, developing, reactive ion etching (RIE), and photoresist removal processes to obtain a patterned two-dimensional material. However, these steps have complicated process, high cost, and large time consumption, and may introduce impurity particles to the material surface.

Chinese patent publication No. 115763219A provides a method for simply, efficiently, and economically preparing single-layer patterned two-dimensional materials, which is applicable to the formation of two-dimensional material arrays within a size of 3 mm×3 mm (for example, for the MoS₂ particle with a size of 20 μm, about a few thousand MoS₂ arrays can be obtained), but is not suitable for the transfer of a large-area film (e.g., MoS₂ film with a diameter of 5 cm). In order to meet the existing commercial need for large-area integration of micro-LED grains, it is required to enable the two-dimensional material transfer technology to be applied to the wafer-scale substrate, to achieve the mass transfer of wafer-scale two-dimensional material arrays.

However, at least the following problems exist in the prior art. The existing low-cost, efficient, and simple transfer method of two-dimensional TMDs material arrays cannot satisfy the integration of large-scale micro-LEDs. Therefore, there is a need to develop a low-cost, repeatable, and fast transfer method of high-density two-dimensional materials that can be applied to wafer-scale substrates, so as to achieve the large-scale integration.

### SUMMARY

To overcome the defects in the prior art that it fails to prepare wafer-scale single-layer patterned two-dimensional materials, this application provides a method for preparing wafer-scale two-dimensional (2D) material arrays.

Technical solutions of this application are described as follows.

This application provides method for preparing a wafer-scale two-dimensional (2D) material array, comprising:
(a) mixing water and an alcohol solvent to obtain a mixed solution;
(b) preparing a polydimethylsiloxane (PDMS) stamp as a support layer, wherein an upper surface of the PDMS stamp is provided with a plurality of micro posts in periodic arrangement;
(c) continuously growing a monolayer two-dimensional transition metal dichalcogenides (2D-TMDs) film on a growth substrate;
(d) putting the PDMS stamp upside down to allow the plurality of micro posts to be in contact with the monolayer 2D-TMDs film, so as to obtain a PDMS stamp-2D-TMDs film-growth substrate combination;
(e) immersing the PDMS stamp-2D-TMDs film-growth substrate combination in the mixed solution to separate the monolayer 2D-TMDs film from the growth substrate;
(f) removing a portion of the monolayer 2D-TMDs film which is not in contact with upper surfaces of the plurality of micro posts, so as to obtain a patterned 2D-TMDs film; and
(g) transferring the patterned 2D-TMDs film onto a target substrate to obtain the wafer-scale 2D material array.

In an embodiment, the alcohol solvent is ethanol or isopropanol.

In an embodiment, a volume ratio of water to the alcohol solvent in the mixed solution is (1˜2): 1.

In an embodiment, a volume ratio of water to the alcohol solvent in the mixed solution is (1˜1.5): 1.

In an embodiment, a volume ratio of water to the alcohol solvent in the mixed solution is 1:1.

In an embodiment, the step (b) is performed through the following steps:
designing a patterned mold; filling the patterned mold with PDMS through spin-coating; curing the PDMS within the patterned mold; and demolding cured PDMS from the patterned mold to obtain the patterned PDMS stamp.

In an embodiment, the step (g) is performed through the following steps:
allowing the plurality of micro posts to be in contact with the target substrate such that the patterned 2D-TMDs film adheres to the target substrate; and separating the PDMS stamp from the patterned 2D-TMDs film to transfer the patterned 2D-TMDs film onto the target substrate.

In an embodiment, the step of separating the PDMS stamp from the patterned 2D-TMDs film to transfer the patterned 2D-TMDs film onto the target substrate comprises:
heating the target substrate to a predetermined temperature; and lifting the PDMS stamp to separate the PDMS stamp from the patterned 2D-TMDs film, thereby completing transfer of the patterned 2D-TMDs film to the target substrate.

In an embodiment, the target substrate is a silicon dioxide layer-containing silicon substrate, a glass substrate, a flexible polyimide substrate or a flexible polyethylene terephthalate substrate.

In an embodiment, an area of the growth substrate is not smaller than that of the PDMS stamp; and an area of the target substrate is not smaller than that of the PDMS stamp.

Compared to the prior art, this application has the following beneficial effects.

By adopting a patterned PDMS stamp and employing a water-ethanol or water-isopropanol mixture as the transfer medium, this application achieves the transfer of a wafer-scale patterned two-dimensional material film with simpler operation, higher cost-effectiveness, less time consumption and excellent repeatability.

### BRIEF DESCRIPTION OF THE DRAWINGS

In order to illustrate the technical solutions in the embodiments of the present disclosure or the prior art more clearly, the drawings required in the description of the embodiments or the prior art will be briefly described below. Obviously, presented in the drawings are merely some embodiments of the present disclosure, which are not intended to limit the disclosure. For those skilled in the art, other drawings may also be obtained according to the drawings provided herein without paying creative efforts.

FIG. 1 is a flowchart of a method for preparing a wafer-scale two-dimensional material array according to an embodiment of the present disclosure;

FIG. 2a is a structural diagram of a PDMS stamp according to an embodiment of the present disclosure;

FIG. 2b is a partially enlarged view of FIG. 2a;

FIG. 3a schematically shows a growth substrate and a monolayer 2D-TMDs film according to an embodiment of the present disclosure;

FIG. 3b is a partially enlarged view of FIG. 3a;

FIG. 4a schematically shows that the PDMS stamp is put upside down so that micro posts are in intimate contact with the 2D-TMDs film;

FIG. 4b is a partially enlarged view of FIG. 4a;

FIG. 5a is a schematic view of the single-layer 2D-TMDs after being transferred to an upper surface of the micro posts according to an embodiment of the present disclosure;

FIG. 5b is a partially enlarged view of FIG. 5a;

FIG. 6 schematically shows the transfer of a patterned 2D-TMDs film to a target substrate according to an embodiment of the present disclosure;

FIG. 7a is a schematic view of the patterned 2D-TMDs film after being transferred to the target substrate;

FIG. 7b is a partially enlarged view of FIG. 7a;

FIG. 8 is an optical microscopy image of the monolayer 2D-TMDs film grown on the growth substrate by a chemical vapor deposition (CVD) process according to an embodiment of the present disclosure;

FIG. 9 is an optical microscopy image of the micro posts in intimate contact with the monolayer 2D-TMDs film according to an embodiment of the present disclosure;

FIG. 10 is an optical microscopy image of the patterned 2D-TMDs film transferred to the PDMS stamp according to an embodiment of the present disclosure;

FIG. 11 is an optical microscopy image of the patterned 2D-TMDs film transferred to the target substrate according to an embodiment of the present disclosure;

FIG. 12a is an optical microscopy image of the patterned PDMS stamp according to an embodiment of the present disclosure at 50× magnification;

FIG. 12b is an optical microscopy image of the patterned PDMS stamp at 100× magnification;

FIG. 12c is an optical microscopy image of the patterned PDMS stamp at 200× magnification;

FIG. 12d is an optical microscopy image of the patterned PDMS stamp at 500× magnification;

FIG. 13a is an optical microscopy image of a first patterned 2D-TMDs film transferred to a target substrate at 50× magnification;

FIG. 13b is an optical microscopy image of the first patterned 2D-TMDs film transferred to the target substrate at 100× magnification;

FIG. 13c is an optical microscopy image of the first patterned 2D-TMDs film transferred to the target substrate at 200× magnification;

FIG. 13d is an optical microscopy image of the first patterned 2D-TMDs film transferred to the target substrate at 500× magnification;

FIG. 14a is an optical microscopy image of a second patterned 2D-TMDs film transferred to a target substrate at 100× magnification;

FIG. 14b is an optical microscopy image of the second patterned 2D-TMDs film transferred to the target substrate at 200× magnification;

FIG. 15a shows a contact angle of a drop of water on the target substrate;

FIG. 15b shows a contact angle of a drop of a water-ethanol mixture (in a volume ratio of 1:1) on the target substrate;

FIG. 16a shows a contact angle of a drop of water on the PDMS stamp;

FIG. 16b is a contact angle of a drop of the water-ethanol mixture (in a volume ratio of 1:1) on the PDMS stamp;

FIG. 17a is an optical microscopy image of a 2D transistor prepared based on a transferred patterned 2D-TMDs film at 200× magnification;

FIG. 17b is an optical microscope image of the 2D transistor prepared based on the transferred patterned 2D-TMDs film at 1000× magnification;

FIG. 17c illustrates an output characteristic curve of a 2D transistor according to an embodiment of the present disclosure, where an inset schematically shows the electric connection;

FIG. 17d illustrates a transfer characteristic curve of a 2D transistor according to another embodiment of the present disclosure;

FIG. 18a illustrates an output characteristic curve obtained by testing 1000 2D transistors; and

FIG. 18b is a current distribution plot obtained by testing 1000 2D transistors.

In the figures: 1—PDMS stamp; 2—micro post; 3—monolayer 2D—TMDs film; 4—growth substrate; 5—target substrate; 6—patterned 2D—TMDs film.

### DETAILED DESCRIPTION OF EMBODIMENTS

The technical solutions in the embodiments of the present disclosure will be clearly and completely described below in conjunction with the accompanying drawings of the present disclosure. Obviously, described below are merely some embodiments of the disclosure, which are not intended to limit the disclosure. For those skilled in the art, other embodiments obtained based on these embodiments without paying creative efforts should fall within the scope of the disclosure.

The disclosure will be further described in detail in conjunction with the specific embodiments. The technical details not introduced in the embodiments can be referred to the relevant descriptions in the previous section.

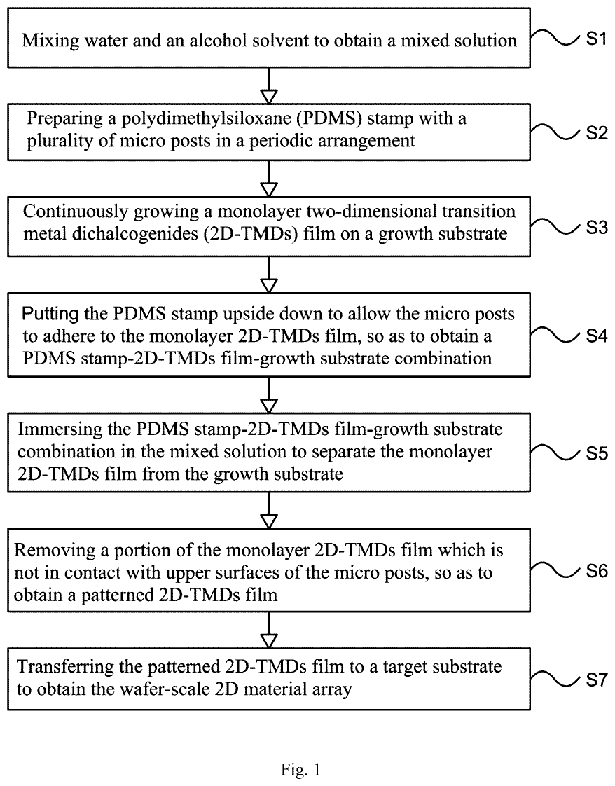

As shown in FIG. 1, to achieve the cost-effective, repeatable, and rapid transfer of patterned wafer-scale two-dimensional (2D) materials, this disclosure provides a method for preparing wafer-scale 2D material arrays. The method eliminates some micromachining processes such as exposure and etching steps, and achieves the 2D material patterning while transferring wafer-scale 2D materials.

In an embodiment, the method includes the following steps.
(a) Water and alcohol solvent are mixed to obtain a mixed solution.
(b) A polydimethylsiloxane (PDMS) stamp 1 with a plurality of micro posts 2 is prepared. The micro posts 2 are distributed on an upper surface of the PDMS stamp 1 in a periodic arrangement.
(c) A monolayer two-dimensional transition metal dichalcogenides (2D-TMDs) film 3 is continuously grown on a growth substrate 4.
(d) The PDMS stamp 1 is put upside down to allow the micro posts 2 to be in contact with the monolayer 2D-TMDs film 3, so as to obtain a PDMS stamp-2D-TMDs film-growth substrate combination.
(e) The PDMS stamp-2D-TMDs film-growth substrate combination is immersed in the mixed solution to rapidly separate the monolayer 2D-TMDs film 3 from the growth substrate 4.
(f) A portion of the monolayer 2D-TMDs film 3 which is not in contact with upper surfaces of the micro posts 2 is removed to obtain a patterned 2D-TMDs film 6.
(g) The patterned 2D-TMDs film 6 is transferred onto a target substrate 5 to obtain the wafer-scale 2D material array.

The successful introduction of 2D-FETs by AIEC into a 300 mm silicon process line in 2019 confirms the compatibility with the back-end-of-line (BEOL) process, which provides a possible route for the research and development of devices in the post-Moore era. In addition, due to the continuous optimization of preparation process of the low contact resistance metals and the dielectric insulating layer, the 2D MoS₂-based field-effect transistors (MoS₂-FET) have on-state current values (I_{ON}=˜1.27 mA/um) and high mobility (122.6 cm²V⁻¹s⁻¹) comparable to those of low temperature poly-silicon (LTPS-TFTs). The MoS₂-FETs are comparable to oxide semiconductors (e.g., indium-gallium-zinc-oxide thin-film transistors (IGZO-TFTs)) in terms of leakage current (10⁻¹³ μA/μm), which demonstrates its application potential in the construction of 2D pixel circuits (e.g., image sensors, photovoltaic imaging, display driver circuits). Currently, some researches have been carried out about the 2D device-based functional circuits. For example, a 32×32 MoS₂-FETs pixel circuit has been prepared by monolithic integration of MoS₂-FET with a Micro-LED display chip through a back-end-of-line (BEOL) process, and the driving function of micro-LED display matrices has been preliminarily verified. In terms of the display performance, for a micro-LED display with a resolution of 320×240 pixels, 76,800 grains need to be integrated; and for a micro-LED display with a resolution of 1280×720 pixels, more than 770,000 grains need to be integrated. Therefore, in order to adapt to the large-scale integration, it is necessary to prepare wafer-scale 2D-TMDs materials, and 2D-TMDs materials are patterned.

The wafer refers to the size of the silicon slice, such as 2 inches, 4 inches, 8 inches, and 12 inches. 2 inches indicate a silicon slice with a diameter of 5 cm. For example, for the MoS₂ particle with a size of 20 μm, about a few thousand MoS₂ arrays can be obtained, but it is not suitable for the transfer of a large-area film (e.g., MoS₂ film with a diameter of 5 cm. The disclosure can transfer MoS₂ films with a diameter of 5 cm (2 inches) in a single pass by formulating a suitable mixed solution as a transfer medium. As a result, more than 1 million MoS₂ arrays can be obtained on the 2-inch wafer. In this embodiment, the mixed solution consists of water and ethanol or consists of water and isopropanol. The mixed solution has less polarity and better wettability than pure water. The polarity of the mixed solution (i.e., the contact angle of the drop with the growth substrate 4, and the contact angle of the drop with the PDMS stamp 1) is regulated by different mixing ratios, so as to rapidly separate the monolayer 2D-TMDs film 3 from the growth substrate 4.

The preparation of the 2-inch patterned 2D-TMDs film 6 was taken as an example to illustrate the specific steps.

500 mL of a water-ethanol mixed solution was prepared.

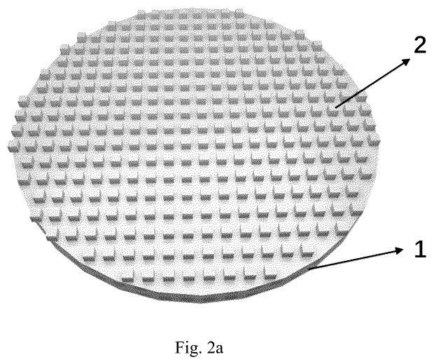

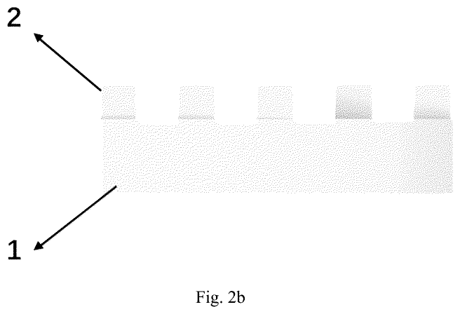

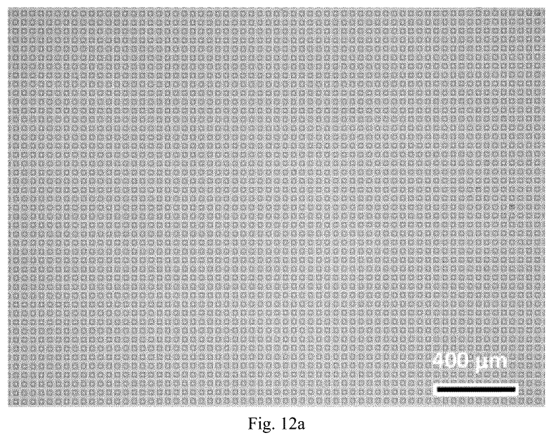

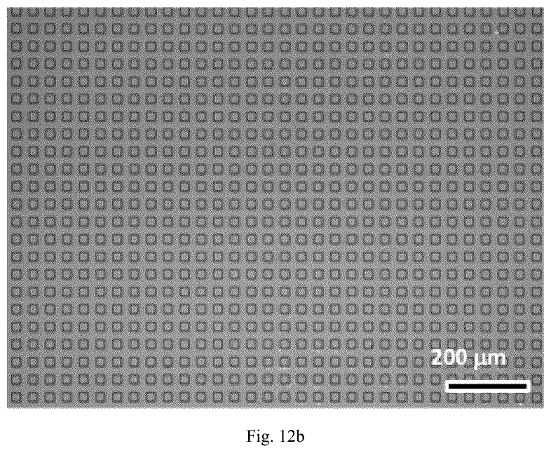

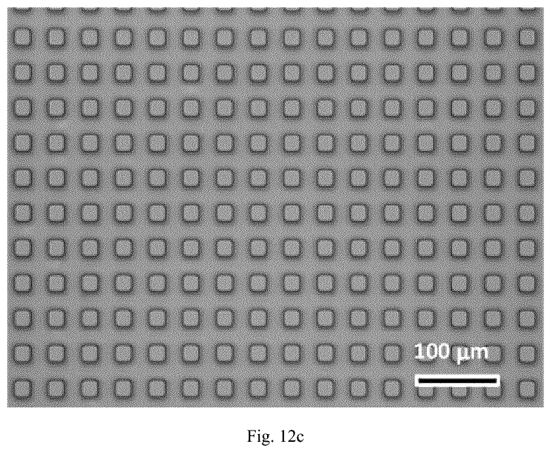

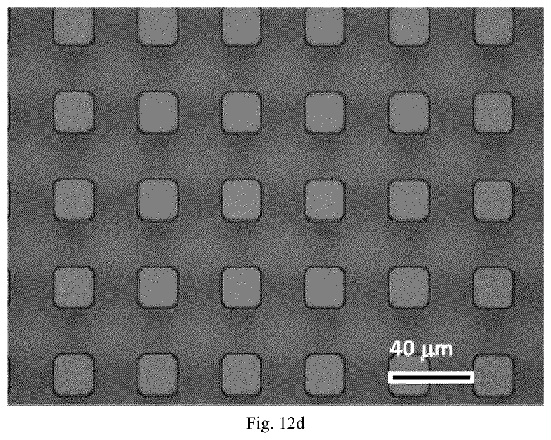

As shown in FIGS. 2a and 2b, a 4-inch PDMS stamp 1 was first prepared. The 4-inch PDMS stamp 1 had micro posts 2 in a periodic and regular arrangement. The upper surface of the micro posts 2 was flat, smooth, and adhesive. FIGS. 12a, 12b, 12c, and 12d were optical microscopy images of the patterned PDMS stamp 1 at different magnifications, namely, images of the PDMS stamp 1 with micro posts 2 in the periodic and regular arrangement. The size of each micro post 2 was 20×20×20 m (length×width×height), and the spacing between the micro posts 2 was 20 m.

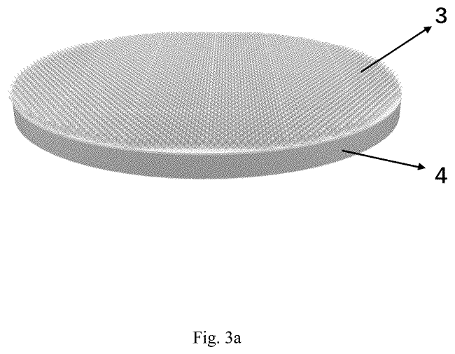

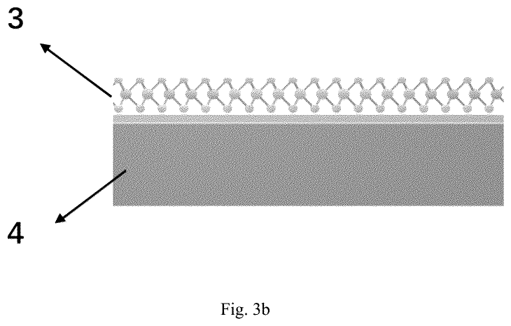

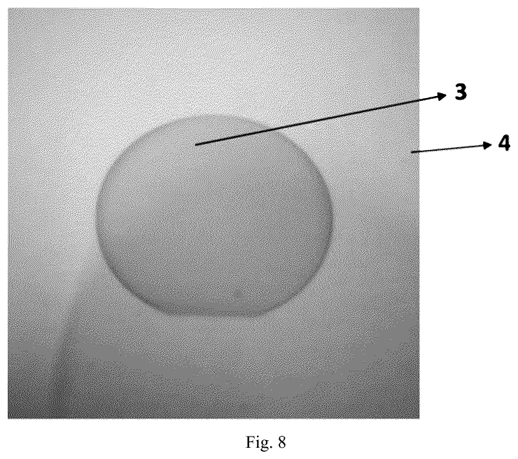

As shown in FIGS. 3a and 3b, a uniform and continuous monolayer 2D-TMDs film 3 was grown on a 2-inch growth substrate 4 by a CVD process. FIG. 8 showed the uniform and continuous monolayer 2D-TMDs film 3 grown on the growth substrate 4.

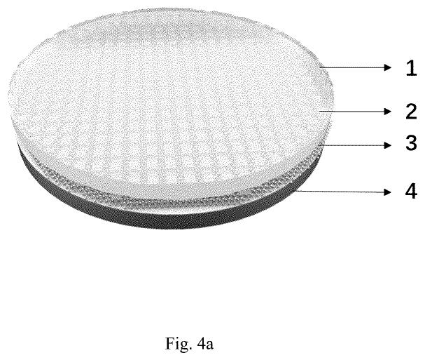

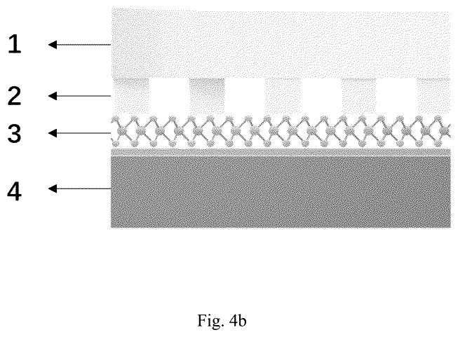

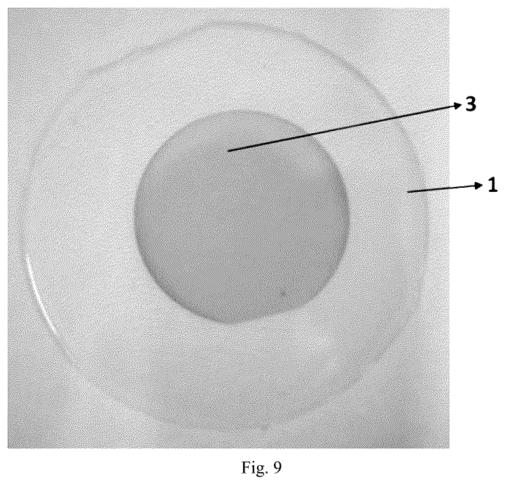

As shown in FIGS. 4a and 4b, the PDMS stamp 1 was put upside down so that the micro posts 2 were in contact with the monolayer 2D-TMDs film 3. The PDMS stamp 1 was subjected to external pressure, and the upper surfaces of the micro posts 2 were in intimate contact with the surface of the monolayer 2D-TMDs film 3. At this time, the area between the PDMS stamp 1 and the monolayer 2D-TMDs film 3 was divided into two different regions: a contact region, in which the micro posts 2 were in intimate contact with the monolayer 2D-TMDs film 3; and a non-contact region, i.e., an area between the micro posts 2, which was equivalent to a micrometer-sized capillary tube. FIG. 9 was an optical microscopy image of the micro posts in intimate contact with the monolayer 2D-TMDs film.

The mixed solution was poured into a wide-mouth container (greater than 4 inches in diameter). As shown in FIGS. 4a and 4b, the PDMS stamp 1 and the growth substrate 4 having the monolayer 2D-TMDs film 3 were immersed together in the mixed solution, where the PDMS stamp 1, the monolayer 2D-TMDs film 3, and the growth substrate 4 were in close contact with each other.

Due to the lower polarity, the mixed solution could easily penetrate into the interface between the monolayer 2D-TMDs film 3 and the substrate along the non-contact region, facilitating the rapid separation of the monolayer 2D-TMDs film 3 under the action of the capillary force.

Under the action of the mixed solution, the monolayer 2D-TMDs film 3 in the non-contact region was broken due to the high surface tension of the liquid. The monolayer 2D-TMDs film 3 in the contact region remained intact under the action of the inherent viscosity of the micro posts 2.

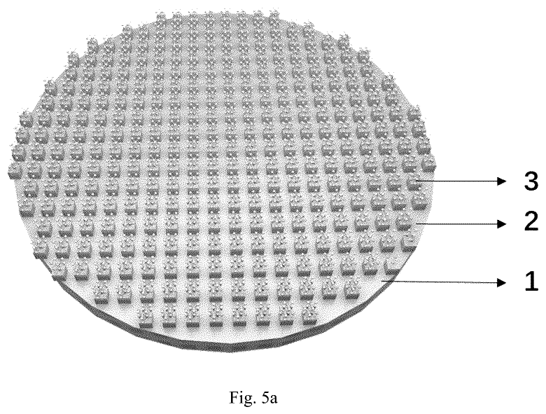

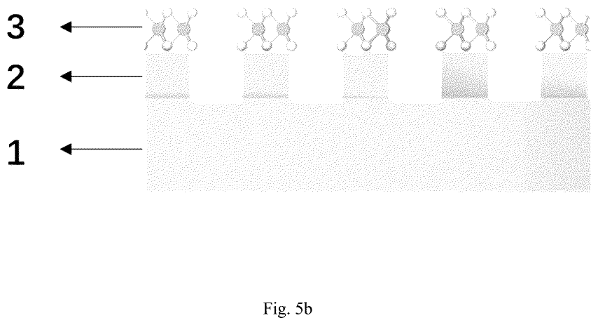

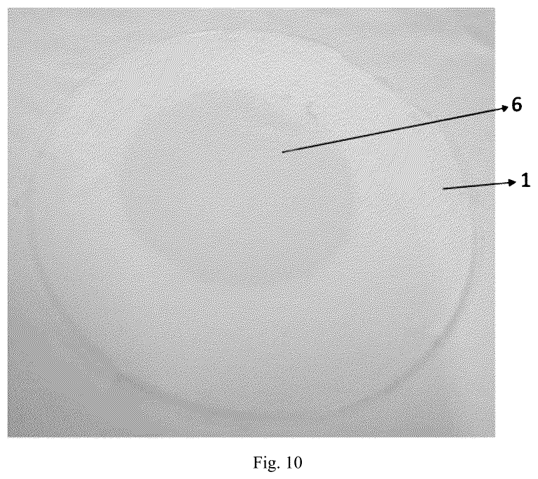

As shown in FIGS. 5a-5b and 10, under the self-adhesion of the micro posts 2, the monolayer 2D-TMDs film 3 was transformed into the periodically and regularly arranged patterned 2D-TMDs film 6, which had the same dimension as the micro posts 2 on the upper surface of the PDMS stamp 1.

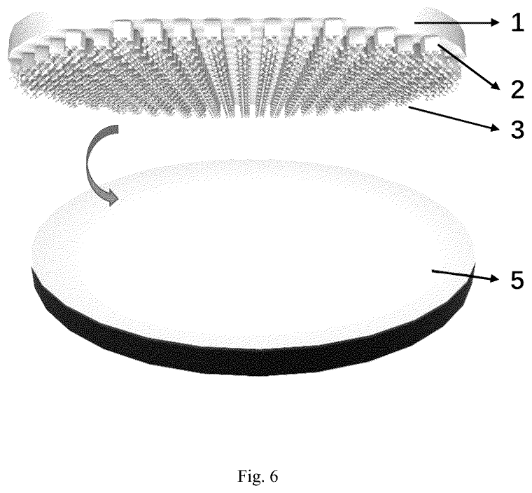

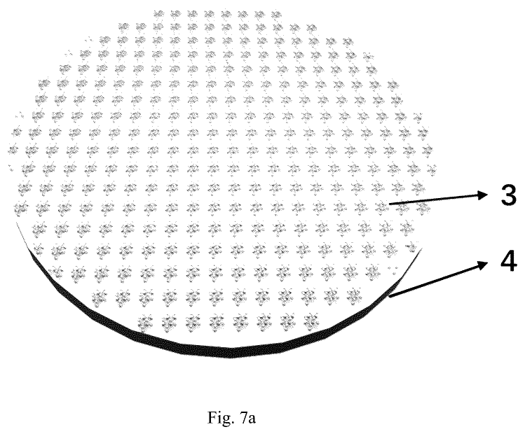

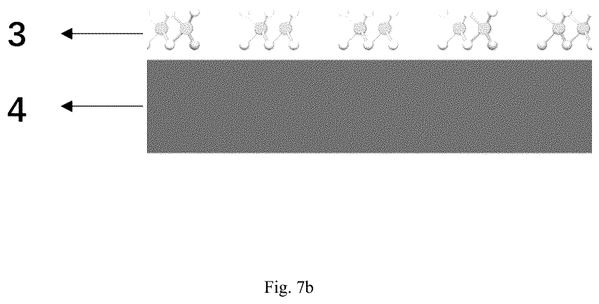

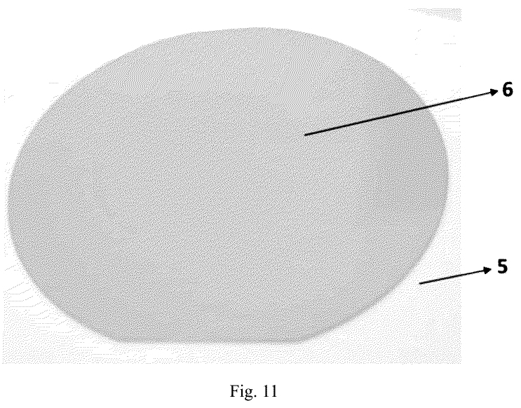

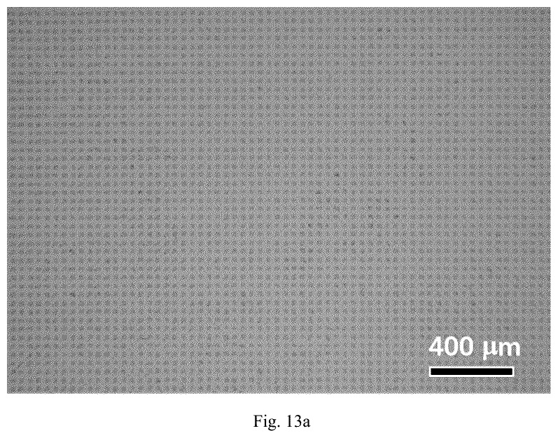

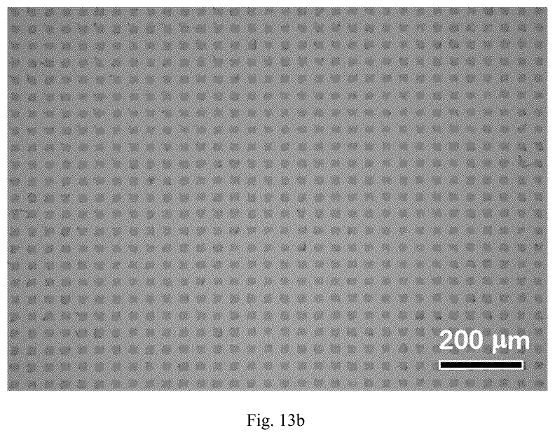

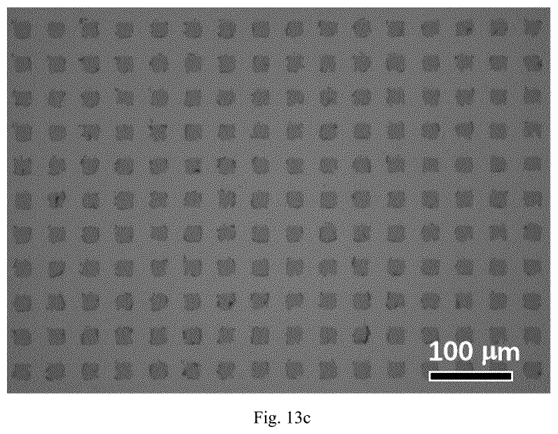

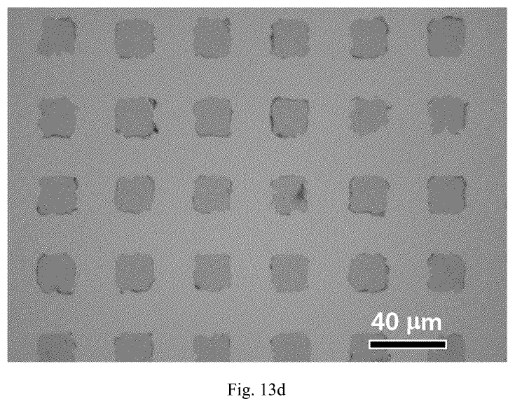

As shown in FIGS. 6, 7a-7b, and 11, the patterned 2D-TMDs film 6 was transferred to the target substrate 5 to obtain 2-inch monolayer patterned 2D materials, i.e., wafer-scale 2D material arrays. High-quality transfer of greater than 1 million crystal arrays can be achieved by a single transfer operation. FIGS. 13a-13d were images of a first patterned 2D-TMDs film 6 under an optical microscope at different magnifications. The first patterned 2D-TMDs film 6 had a periodic and regular arrangement, and had the same size as the micro posts 2 on the upper surface of the PDMS stamp 1.

In an embodiment, the alcohol solvent was ethanol or isopropanol. Ethanol and isopropanol were readily available and relatively cheap, and thus were commonly used as alcohol solvent.

In an embodiment, the volume ratio of water to the alcohol solvent in the mixed solution was (1-2): 1. Within such volume ratio range, the mixed solution had a polarity, which made it suitable as a transfer medium to separate the monolayer 2D-TMDs film 3 from the growth substrate 4. Excessive water in the mixed solution would affect the transfer rate, and insufficient water would damage the material.

Preferably, the volume ratio of water to alcohol solvent in the mixed solution was (1-1.5): 1. By further narrowing the volume ratio range, the polarity of the mixed solutions in this range allowed for a better transfer rate.

Preferably, the volume ratio of water to the alcohol solvent in the mixed solution was 1:1, thereby facilitating the preparation of the mixed solution and the separation of the monolayer 2D-TMDs film 3 from the growth substrate 4.

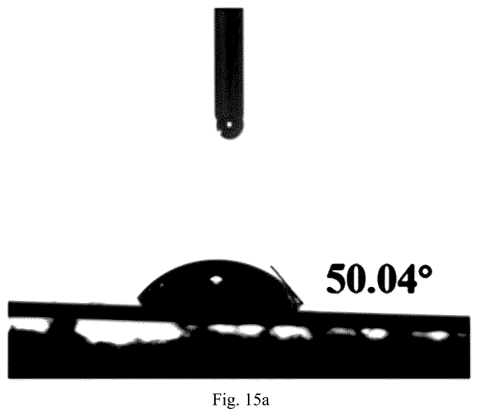

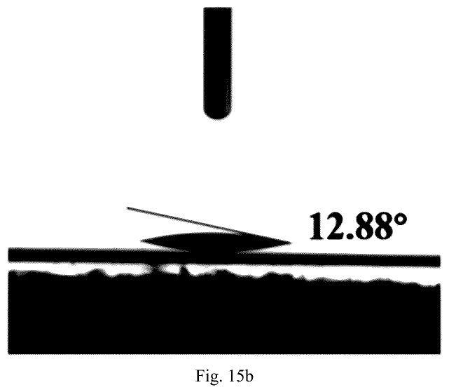

As shown in FIG. 15a, when water was selected as the transfer medium, the contact angle of the water droplet on the surface of the target substrate 5 was 50.04°. As shown in FIG. 15b, when a water-ethanol mixed solution was selected as the transfer medium, the contact angle of the droplet of the mixed solution on the surface of the target substrate 5 was 12.88°. A smaller contact angle indicated higher surface wettability.

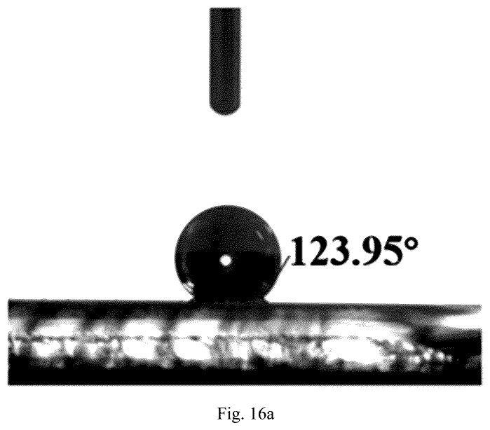

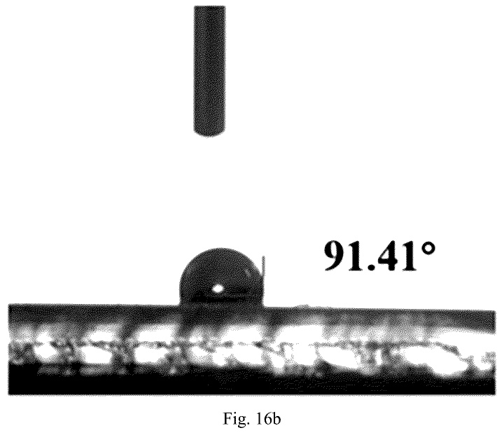

As shown in FIG. 16a, when water was selected as the transfer medium, the contact angle of the droplets of water on the surface of the PDMS stamp was 123.95°. FIG. 16b showed that when the mixed solution of water and ethanol was selected as the transfer medium, the contact angle of the droplets of the mixed solution on the surface of the PDMS stamp 1 was 91.41°. A larger contact angle indicated that the PDMS stamp 1 was more hydrophobic, and the droplets were more likely to aggregate into small balls on the surface of the PDMS stamp 1.

The non-contact region could be simplified as the micron-scale capillary. As shown in FIGS. 15a-15b and 16a-16b, the contact behavior within the capillary region formed the curved liquid surface. The pressure (Pin) inside the liquid and the pressure (Pout) outside the liquid were different. AP represented the Laplace pressure (Pin-Pout) in the capillary, which related to the contact angle of pure water. The Laplace equation can be expressed as:

$$Δ {P}_{1} = \frac{{γ}_{1}}{h} ( cos {θ}_{1} + cos {θ}_{2} ) ,$$

where h represented a capillary height; γₗ represented surface tension of the liquid; and θ₁ and θ₂were the contact angles of the droplets on the target substrate 5 and the PDMS surface 1, respectively.

Laplace pressure inside the capillary was calculated with different solutions, respectively. Under pure water conditions, the contact angles of the droplets on the SiO₂/Si substrate and the patterned PDMS surface were 50.04° and 123.95°, respectively. Thus,

$$Δ P = \frac{{γ}_{1}}{h} [ cos ( 50.04 ° ) + cos ( 123.95 ° ) ] = \frac{72.9}{h} [ 0.642 - 0.558 ] = \frac{{γ}_{1}}{h} \times 0.084 .$$

The value γₗ of pure water was estimated to be about 72.20×10⁻³ N/m, and h was 20 μm. Therefore, the calculated ΔP₁ was about 0.3 kPa.

For the water-ethanol mixed solution in a volume ratio of 2:1, the contact angles of a droplet on the surfaces of the target substrate 5 and PDMS stamp 1 were 43.04° and 108.91°, respectively. Therefore, the

$$Δ P = \frac{{γ}_{1}}{h} [ cos ( 43.04 ° ) + cos ( 108.91 ° ) ] = \frac{29.5}{h} [ 0.731 - 0.324 ] = \frac{{γ}_{1}}{h} \times 0.407 .$$

The value γₗ of the mixed solution was estimated to be about 33.58×10⁻³ N/m, and h was 20 μm. Therefore, the calculated ΔP₂ was about 0.68 kPa.

For the water-ethanol mixed solution in a volume ratio of 1:1, the contact angles of a droplet on the surfaces of the target substrate 5 and the PDMS stamp 1 were 91.41° and 12.88°, respectively. Therefore,

$$Δ P = \frac{{γ}_{1}}{h} [ cos ( 12.88 ° ) + cos ( 91.41 ° ) ] = \frac{27}{h} [ 0.975 - 0.025 ] = \frac{{γ}_{1}}{h} \times 0.95 .$$

The value γₗ of the mixed solution was estimated to be about 28.51×10⁻³ N/m, and h was 20 μm, so the calculated ΔP₃ was about 1.35 kPa.

ΔP₃ was 4.50 times larger than ΔP₁, indicating that the water-ethanol mixed solution was more permeable. Thus, a low-polarity solution was essential for the fast transfer of 2D arrays.

Further, the step of “preparing a polydimethylsiloxane (PDMS) stamp 1 with a plurality of micro posts 2 in the periodic and regular arrangement” was performed through the following steps.

A patterned mold was designed.

The patterned mold was filled with PDMS by spin-coating.

The PDMS within the patterned mold was cured to obtain the cured PDMS.

The cured PDMS was demolded from the patterned mold to obtain the patterned PDMS stamp.

The PDMS stamp 1 was obtained by adopting the patterned mold, for example the SU-8 patterned mold, which was designed to meet the requirements (e.g., shape of the pattern, arrangement, and size). PDMS was coated into the patterned mold by the spin coating method. Under the action of centrifugal force, the patterned mold was spin-coated and filled with PDMS to form a flat and smooth surface. Since PDMS was a viscous liquid, the curing mold need to be cured after filling the PDMS inside the curing mold. After curing, the PDMS was demolded from the patterned mold, thereby obtaining the patterned PDMS stamp 1. As shown in FIGS. 2a-2b and 12a-12d, the micro posts 2 on the PDMS stamp 1 were arranged in the predetermined pattern, and the upper surfaces of the micro posts 2 were flat, smooth, and adhesive.

The process for continuously growing a monolayer 2D-TMDs film on the growth substrate was performed by chemical vapor deposition (CVD), metal-organic chemical vapor deposition (MOCVD), or plasma-enhanced chemical vapor deposition (PECVD). The 2D-TMDs films include molybdenum disulfide (MoS₂), tungsten selenide (WSe₂), or tungsten disulfide (WS₂), or molybdenum selenide (MoSe₂), or molybdenum telluride (MoTe₂).

The CVD, MOCVD, and PECVD were all capable of generating the monolayer 2D-TMDs film 3. The selected TMDs thin film can be a monolayer and continuous MoS₂ thin film, or WSe₂ thin film, WS₂ thin film, MoSe₂ thin film, or MoTe₂ thin film. The monolayer contiguous TMDs film was uniformly distributed on the growth substrate 4.

The step of “transferring the patterned 2D-TMDs film 6 onto a target substrate 5 to obtain the wafer-scale 2D material array” was performed through the following steps.

The plurality of micro posts 2, to which the patterned 2D-TMDs film 6 was adhered, were in intimate contact with the target substrate 5 such that the patterned 2D-TMDs film 6 was allowed to adhere to the target substrate 5.

The patterned 2D-TMDs film 6 was separated from the PDMS stamp 1 to be transferred to the target substrate 5.

As shown in FIG. 6, the PDMS stamp 1, where the upper surfaces of the micro posts 2 were adhered to the patterned 2D-TMDs film 6 as shown in FIGS. 5a-5b, was put upside down, and allowed to be in contact with the target substrate 5. Then, an external force was applied to the PDMS stamp 1, and under the action of the external force, the patterned 2D-TMDs film 6 on the upper surfaces of the micro posts 2 was adhered and transferred to the target substrate 5. The PDMS stamp 1 was then slowly lifted to separate the patterned 2D-TMDs film 6 from the micro posts 2.

The step of separating the PDMS stamp 1 from the patterned 2D-TMDs film 6 to transfer the patterned 2D-TMDs film 6 onto the target substrate 5 was performed through the following steps.

The target substrate 5 was heated to a predetermined temperature.

The PDMS stamp 1 was lifted to separate the PDMS stamp 1 from the patterned 2D-TMDs film 6, thereby completing the transfer of the patterned 2D-TMDs film 6 to the target substrate 5.

In order to reduce the stickiness of the PDMS stamp 1, the PDMS stamp-patterned 2D-TMDs film-target substrate was placed onto a heating plate. The heating plate was heated to 80° C.-100° C. within three minutes, preferably 100° C., to reduce the viscosity of the PDMS to 0. The PDMS stamp 1 was lifted after the preset temperature was reached, to separate the patterned 2D-TMDs film 6 from the micro posts 2.

The target substrate 5 was a silicon dioxide layer-containing silicon substrate, a glass substrate, a flexible polyimide substrate or a flexible polyethylene terephthalate substrate.

The target substrate 5 in FIG. 6 was a 1 cm×1 cm silicon substrate containing a silicon dioxide layer with a thickness of about 300 nm. The glass substrate, the flexible polyimide substrate or the flexible polyethylene terephthalate substrate can also be selected as the substrate.

The area of the growth substrate 4 was not smaller than the area of the PDMS stamp 1, and the area of the target substrate 5 was not smaller than the area of the PDMS stamp 1.

The micro posts 2 on the PDMS stamp 1 served as carriers for preparing and transferring the patterned 2D-TMDs film 6. If the area of the growth substrate 5 was smaller than the PDMS stamp 1, the micro posts 2 on the PDMS stamp 1 will not be fully covered by the monolayer 2D-TMDs film 3, and thus it failed to obtain the patterned 2D-TMDs film 6 in the predetermined arrangement. the grown continuous monolayer 2D-TMDs film 3 adhered to the upper surfaces of the micro posts 2, and then was transferred to the target substrate 5 by means of the surface viscosity of the micro posts 2 on the PDMS stamp 1. If the area of the target substrate 5 was smaller than the PDMS stamp 1, only a portion of the micro posts 2 could have a contact with the target substrate 5, and only a part of the patterned 2D-TMDs film 6 could be transferred, thereby failing to arrive at the patterned 2D materials in a predefined arrangement on the target substrate 5.

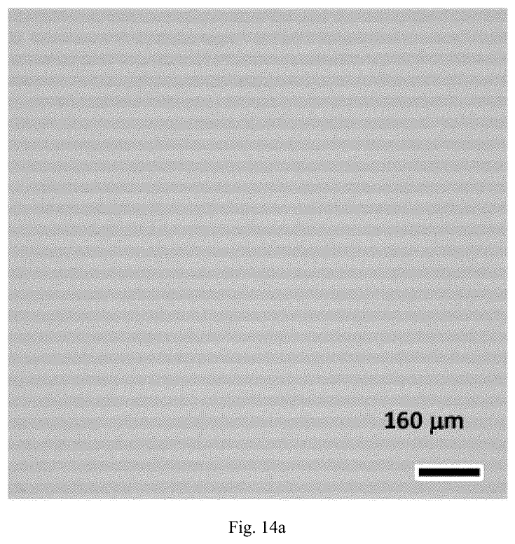

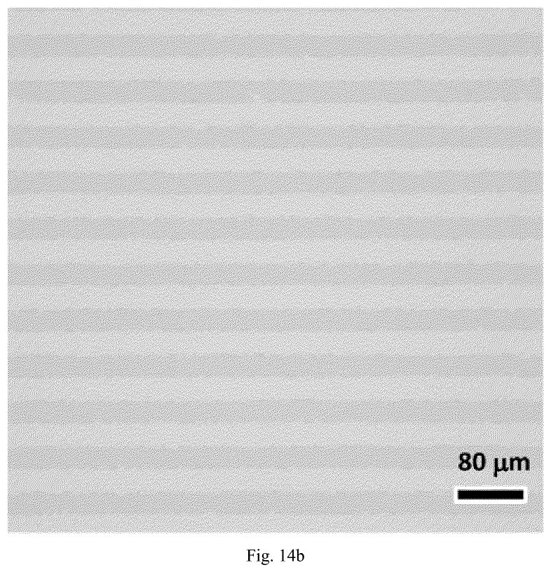

FIGS. 14a-14b were optical microscope images of the patterned 2D-TMDs films 6 which were patterned with 2D material micron strips based on the same transfer process by changing the pattern of the PDMS stamp 1, i.e., replacing regular micro posts with regular PDMS micron strips. The width of the 2D material micron strips was m, and the spacing between adjacent micron strips was 20 m. The method provided herein enables a repeatable transfer process.

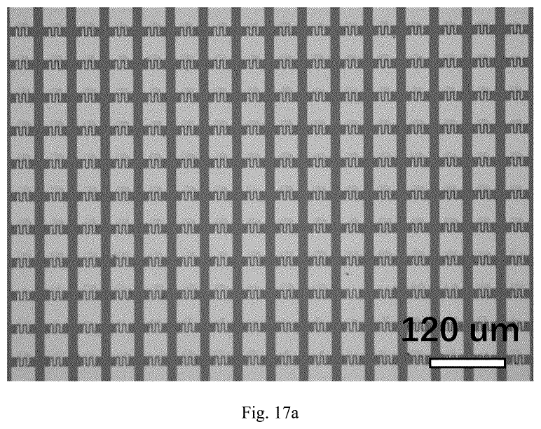

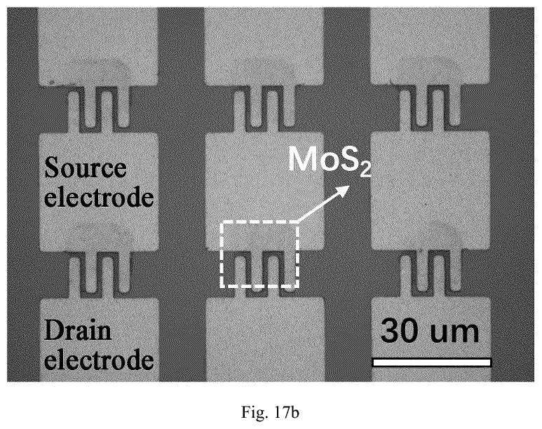

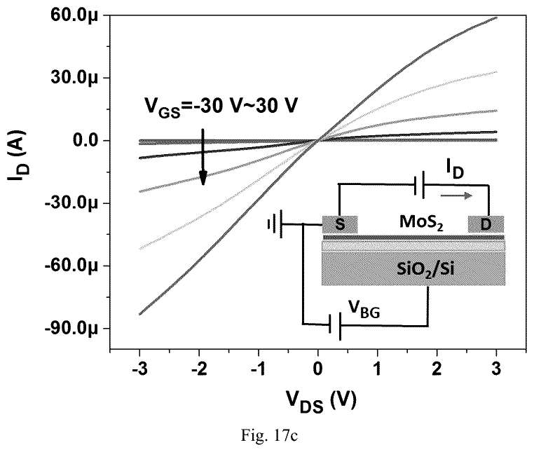

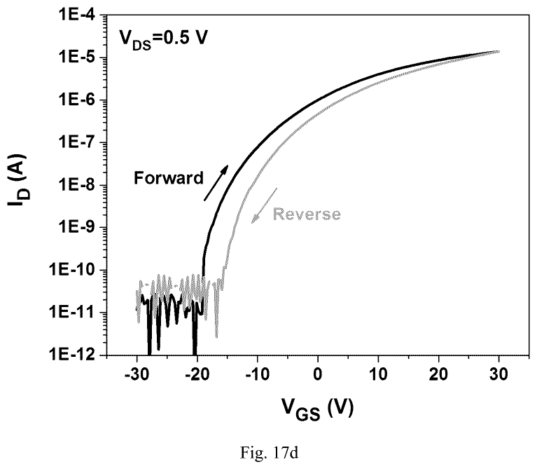

The patterned 2D material prepared by the method of the disclosure was applied to the preparation of 2D material transistors. FIGS. 17a-17b showed 2D material transistors prepared by the transferred patterned 2D-TMDs film 6. Taking the 2D material MoS₂ as an example, the specific preparation process mainly included: spin-coating a layer photoresist on the surface of MoS₂ array; baking the photoresist at 150° C. for 110 seconds; exposing the desired electrode pattern with a laser direct-write device; developing the electrode using a developer solution; using an electron beam evaporation device to deposit Cr/Au (5 nm/30 nm) electrodes as source (S) electrode and drain (D) electrode for the MoS₂ channel; performing lift-off using a photoresist-removing solution to obtain patterned MoS₂-FETs, i.e., MoS₂-FET arrays.

FIGS. 17c and 17d showed respectively output characteristic curves and transfer characteristic curves of the 2D material-based transistors. The inset in FIG. 17c showed the corresponding circuit connection. A semiconductor analyzer (B1500A) device was used to test the output characteristic curves of the MoS₂-FETs.

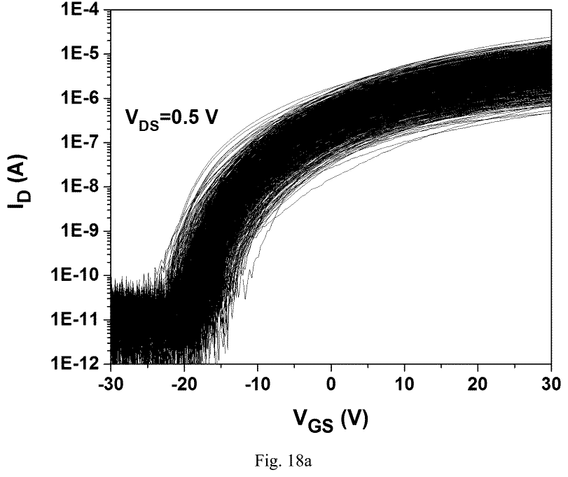

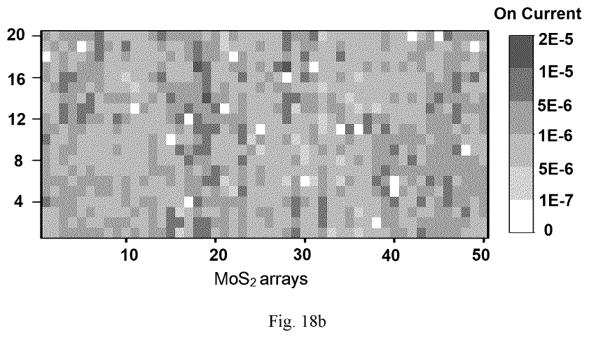

FIG. 18a showed that the 2D material transistors produced by the patterned 2D material prepared by the method provided by the disclosure were tested. For example, 1000 MoS₂ transistors (20×50 MoS₂ arrays) were tested, and 979 output characteristic curves were obtained statistically. FIG. 18b showed current (I_{D}) distribution plot obtained by testing the 2D material transistors, for example, 1000 MoS₂ transistors (20×50 MoS₂ arrays) were tested, and the distribution graph of current (I_{D}) was statistically obtained. The test results showed that the 2D material transistors produced by the 2D materials prepared by the method in the disclosure had good consistency.

The disclosure can achieve low-cost, repeatable, and fast transfer of wafer-scale 2D arrays. The method eliminates the need for microfabrication processes, such as exposure step and etching step, and patterns 2D-TMDs film 3 while transferring wafer-scale 2D-TMDs film 3. The 2D-TMDs film 3 is separated rapidly from the growth substrate 4 by regulating the polarity of the transfer medium, which will greatly enhance the preparation efficiency and reduce the preparation cost. Based on this method, greater than 1 million 2D arrays can be rapidly transferred to the 2-inch wafer in a single operation, thereby facilitating promoting the commercialization of 2D integrated circuits.

It should be understood that the order of steps in the process of the disclosure is exemplary. It should be noted that the order of steps may be rearranged without departing from the protection scope of the present disclosure. The appended method claims give elements of the various steps in exemplary order, which is not intended to limit the disclosure.

In the description above, various features are combined in a single embodiment to simplify the disclosure. This description approach should not be interpreted as reflecting that embodiments of the claimed subject matter require more features than that listed in each claim. On the contrary, as reflected in the appended claims, the disclosure needs fewer features than the individual embodiments disclosed. Accordingly, the appended claims are clearly introduced into the detailed description, wherein each claim stands alone as a separate preferred embodiment of the disclosure.

The embodiments are described above to help those skilled in the art to implement the disclosure. Any modifications and replacements made by those skilled in the art without departing from the spirit of the disclosure should fall within the scope of the disclosure defined by the appended claims. Accordingly, the disclosure is not limited to the embodiments given herein.

The description above includes one or more embodiments. It should be noted that embodiments of the disclosure and the features therein may be combined with each other in the case of no contradiction. Accordingly, the embodiments described herein are intended to cover all such changes, modifications and variations that fall within the protection scope of the appended claims. Furthermore, the term “comprising” used in the specification or the claims covers in a manner similar to the term “including” which is open-ended. In addition, the term “or” in the description is non-exclusive.

The above-described embodiments provide a detailed description of the objects, technical solutions, and beneficial effects of the disclosure. It should be understood that described above are merely preferred embodiments of the disclosure, which are not intended to limit the disclosure. Any modifications, replacements, and improvements made by those skilled in the art without departing from the spirit of the disclosure should fall within the scope of the disclosure defined by the appended claims.

What is claimed is:

1. A method for preparing a wafer-scale two-dimensional (2D) material array, comprising:
(a) mixing water and an alcohol solvent to obtain a mixed solution;
(b) preparing a polydimethylsiloxane (PDMS) stamp as a support layer, wherein an upper surface of the PDMS stamp is provided with a plurality of micro posts in a periodic arrangement;
(c) continuously growing a monolayer two-dimensional transition metal dichalcogenides (2D-TMDs) film on a growth substrate;
(d) putting the PDMS stamp upside down to allow the plurality of micro posts to be in contact with the monolayer 2D-TMDs film, so as to obtain a PDMS stamp-2D-TMDs film-growth substrate combination;
(e) immersing the PDMS stamp-2D-TMDs film-growth substrate combination in the mixed solution to separate the monolayer 2D-TMDs film from the growth substrate;
(f) removing a portion of the monolayer 2D-TMDs film which is not in contact with upper surfaces of the plurality of micro posts, so as to obtain a patterned 2D-TMDs film; and
(g) transferring the patterned 2D-TMDs film to a target substrate to obtain the wafer-scale 2D material array.

2. The method of claim 1, wherein the alcohol solvent is ethanol or isopropanol.

3. The method of claim 1, wherein a volume ratio of water to the alcohol solvent in the mixed solution is (1-2): 1.

4. The method of claim 1, wherein a volume ratio of water to the alcohol solvent in the mixed solution is (1-1.5): 1.

5. The method of claim 1, wherein a volume ratio of water to the alcohol solvent in the mixed solution is 1:1.

6. The method of claim 1, wherein the step (b) is performed through the following steps:
designing a patterned mold;
filling the patterned mold with PDMS through spin-coating;
curing the PDMS within the patterned mold; and
demolding cured PDMS from the patterned mold to obtain the PDMS stamp.

7. The method of claim 1, wherein the step (g) is performed through the following steps:
allowing the plurality of micro posts to be in contact with the target substrate such that the patterned 2D-TMDs film adheres to the target substrate; and
separating the PDMS stamp from the patterned 2D-TMDs film to transfer the patterned 2D-TMDs film to the target substrate.

8. The method of claim 7, wherein the step of separating the PDMS stamp from the patterned 2D-TMDs film to transfer the patterned 2D-TMDs film to the target substrate comprises:
heating the target substrate to a predetermined temperature; and
lifting the PDMS stamp to separate the PDMS stamp from the patterned 2D-TMDs film, thereby completing transfer of the patterned 2D-TMDs film to the target substrate.

9. The method of claim 1, wherein the target substrate is a silicon dioxide layer-containing silicon substrate, a glass substrate, a flexible polyimide substrate or a flexible polyethylene terephthalate substrate.

10. The method of claim 1, wherein an area of the growth substrate is not smaller than that of the PDMS stamp; and an area of the target substrate is not smaller than that of the PDMS stamp.
